(19) United States
(12) Patent Application Publication
(10) Pub. No.: US 2026/0113843 A1
(43) Pub. Date: Apr. 23, 2026

(54) X-CROSS NON-CIRCULAR MICRO VIAS FOR LAYER INTERCONNECT IN PRINTED WIRING BOARD

(71) Applicant: TTM Technologies North America, LLC, St. Louis, MO (US)

(72) Inventor: Paul Steven Denomme, Windermere, FL (US)

(21) Appl. No.: 19/366,265

(22) Filed: Oct. 22, 2025

Related U.S. Application Data
(60) Provisional application No. 63/710,515, filed on Oct. 22, 2024.

(51) Int. Cl. H05K 1/11

(52) U.S. Cl. CPC H05K 1/113; H05K 2201/09563; H05K 2201/09836; H05K 2201/09854

(57) ABSTRACT

A printed circuit board (PCB) may include a first layer including a first plurality of conductive pads spaced apart from each other, a second layer including a second plurality of conductive pads spaced apart from each other, a first plurality of non-circular shaped micro vias connecting between the first plurality of conductive pads of the first layer and the second plurality of conductive pads of the second layer, a third layer including a third plurality of conductive pads spaced apart from each other, and a second plurality of non-circular shaped micro vias connecting between the second plurality of conductive pads of the second layer and the third plurality of conductive pads of the third layer. The second plurality of non-circular shaped micro vias may be rotated at an angle from the first plurality of non-circular shaped micro vias to form an offset pattern along an X-Y plane.

### CROSS-REFERENCE TO RELATED PATENT APPLICATIONS

This patent application claims the benefits under 35 U.S.C. § 119(e) of U.S. Patent Application Serial No. 63/710,515, entitled “X-CROSS NON-CIRCULAR MICRO VIAS FOR LAYER INTERCONNECT IN PRINTED WIRING BOARD,” filed on Oct. 22, 2024, which is incorporated herein by reference in its entirety.

### FIELD

The disclosure is directed to using X-cross non-circular or non-round micro vias for layer interconnect in printed circuit board (PCB) along with using circular pads or rounded square pads for non-breakout layers and non-circular pads for breakout layers.

### BACKGROUND

Using a ball grid array (BGA) is the most common method today for packaging a high pin-count or very dense Application-Specific Integrated Circuits (ASICs) and Field Programmable Gate Arrays (FPGAs). The BGA is a type of surface-mount packaging used for integrated circuits. BGA packages are used to permanently mount devices, such as microprocessors. In the BGA, conductive pads are placed on the bottom of the package. A solder ball sticks to each pad. BGAs have been proven to be a reliable, cost-effective package while providing flexibility to address miniaturization and functional requirements. Many advanced components are placed in BGA packages, ranging from large processors to memory and even small audio chips.

These BGA packages require a “fanout” and routing strategy to reach the pads beneath a BGA component. The term “fanout” routing in PCB design refers to routing channels or traces from the pads or land pattern for the BGA component or refers to routing connections from solder balls of a BGA package to the PCB. The routing connections communicate between the BGA integrated circuits and other components on the PCB. The term “breakout” for BGA means applying routing traces from internal solder balls of the BGA to the perimeter of the BGA prior to general routing of the PCB.

For BGAs, large pitches allow large widths, but large fabrication limits and large pad diameters may force the use of small trace widths. The pitch for BGA is defined as the distance between two adjacent solder balls measured from center to center.

PCB lamination uses heat and pressure to bond multiple layers together, for example, using prepregs. Increasing pin-count and decreasing pin-pitch create significant challenges for PCB designers to reduce the number of lamination layers and thus reduce fabrication costs, while fulfilling signal integrity requirements to meet high-performance goals.

There remains a need for developing routing strategy at reduced costs. There also remains a need for reducing manufacturing costs and improving reliability of micro vias and thus improving production yields.

### BRIEF SUMMARY

In one aspect, a stack of layers for a printed circuit board (PCB) may include a first layer including a first plurality of conductive pads spaced apart from each other. The stack of layers for a PCB is also referred to as PCB or PCB assembly. The stack may also include a second layer including a second plurality of conductive pads spaced apart from each other. The stack may also include a first plurality of non-circular shaped micro vias connecting between the first plurality of conductive pads of the first layer and the second plurality of conductive pads of the second layer. The stack may also include a third layer including a third plurality of conductive pads spaced apart from each other. The stack may also include a second plurality of non-circular shaped micro vias connecting between the second plurality of conductive pads of the second layer and the third plurality of conductive pads of the third layer. The second plurality of non-circular shaped micro vias may be rotated at a first angle from the first plurality of non-circular shaped micro vias to form an offset pattern along an X-Y plane.

In some aspects, the non-circular shaped micro vias may include oval or oblong micro vias. In some aspects, the third layer may be a breakout layer. The third plurality of conductive pads may be non-circular shaped. In some aspects, the stack may further include a fourth layer comprising a fourth plurality of conductive pads spaced apart from each other and a third plurality of non-circular shaped micro vias connecting between the third plurality of conductive pads of the third layer and the fourth plurality of conductive pads of the fourth layer. The third plurality of non-circular shaped micro vias may be rotated at a second angle from the second plurality of non-circular shaped micro vias. In some aspects, the fourth layer may be a breakout layer, and the fourth plurality of conductive pads may be non-circular shaped. In some aspects, the fourth plurality of conductive pads may be oval or oblong shaped. In some aspects, the first angle may range from 0 to 180 degrees.

In some aspects, the third layer may be a breakout layer, and the non-circular shaped vias may include “+” or cross-shaped micro vias. In some aspects, the third plurality of conductive pads may be circular shaped. In some aspects, the stack may further include a fourth layer comprising a fourth plurality of conductive pads spaced apart from each other and a third plurality of non-circular shaped micro vias connecting between the third plurality of conductive pads of the third layer and the fourth plurality of conductive pads of the fourth layer. The third plurality of non-circular shaped micro vias may be rotated at a second angle from the second plurality of non-circular shaped micro vias. In some aspects, the fourth plurality of conductive pads may be circular shaped. In some aspects, the first angle ranges from 0 to 90 degrees.

In some aspects, wherein the second plurality of non-circular shaped micro vias may be aligned with the first plurality of non-circular shaped micro vias along a Z-axis perpendicular to the X-Y plane.

In some aspects, the second plurality of non-circular shaped micro vias may be offset from the first plurality of non-circular shaped micro vias along an X-axis or a Y axis of the X-Y plane.

In another aspect, a stack of layers for a printed circuit board (PCB) may include a ball grid array (BGA). The stack may include a first layer including circular pads or rounded square pads and a first set of routing traces, the circular pads or rounded square pads being divided into a first group of outer circular pads and a second group of inner pads, the first set of routing traces connecting to the first group of outer pads. The stack may also include a second layer including outer non-circular pads, inner circular pads or rounded square pads, and a second set of routing traces connecting to the outer non-circular pads. The stack may also include a third layer including non-circular pads and a third set of routing traces connecting to the non-circular pads of the third layer.

In some aspects, the stack may further include a first plurality of non-circular shaped micro vias connecting between a subset of the second group of the inner pads of the first layer and the outer non-circular pads of the second layer.

In some aspects, the stack may further include a second plurality of non-circular shaped micro vias connecting between the inner circular pads or rounded square pads of the second layer and the non-circular pads of the third layer.

In some aspects, the second plurality of non-circular shaped micro vias may be rotated at an angle from the first plurality of non-circular shaped micro vias to form an offset pattern along an X-Y plane with an offset angle ranging from 0 to 180 degrees.

In some aspects, each of the first plurality and the second plurality of the non-circular shaped micro vias may include oval micro vias.

In some aspects, each of the first plurality and the second plurality of the non-circular shaped micro vias may include “+” or cross-shaped micro vias.

In some aspects, the BGA may have a pitch of 0.4 mm. The BGA may be a 10 by 10 array.

In a further aspect, a stack of layers is provided for a printed circuit board (PCB) including a ball grid array (BGA). The stack may include a first layer including circular pads or rounded square pads and a first set of routing traces, the circular pads or rounded square pads being divided into a first group of outer circular pads and a second group of inner pads, the first set of routing traces connecting to the first group of outer pads. The stack may also include a second layer including non-circular pads and a second set of routing traces connecting to the non-circular pads.

In some aspects, the stack may further include a plurality of non-circular shaped micro vias connecting between a subset of the second group of the inner pads of the first layer and the non-circular pads of the second layer.

In some aspects, the BGA may have a pitch of 0.5 mm. The BGA may be a 6 by 6 array.

Additional embodiments and features are set forth in part in the description that follows and will become apparent to those skilled in the art upon examination of the specification or may be learned by the practice of the disclosed subject matter. A further understanding of the nature and advantages of the disclosure may be realized by reference to the remaining portions of the specification and the drawings, which form a part of this disclosure.

### BRIEF DESCRIPTION OF THE DRAWINGS

The description will be more fully understood with reference to the following figures and data graphs, which are presented as various embodiments of the disclosure and should not be construed as a complete recitation of the scope of the disclosure, wherein:

FIG. 1A illustrates a printed circuit board (PCB) including Layer 1 (L1) to Layer 2 (L2) X-cross oval micro via (μVia) with L1 round pad in accordance with an embodiment of the disclosure;

FIG. 1B illustrates a PCB including L2 to Layer 3 (“L3”) X-cross oval μVia with L2 round pad in accordance with an embodiment of the disclosure;

FIG. 1C illustrates a PCB Layer 3 including L3 oval pad in accordance with an embodiment of the disclosure;

FIG. 2A illustrates a front view (in an X-direction) of a PCB including L1 to Layer 4 (“L4”) oval micro vias (μVias) in accordance with an embodiment of the disclosure;

FIG. 2B illustrates a side view (in a Y-direction) of the PCB including L1 to L4 oval micro vias of FIG. 2A rotated 90° in accordance with an embodiment of the disclosure;

FIG. 2C illustrates a perspective view of the PCB including L1 to L4 oval micro vias of FIG. 2A or FIG. 2B in accordance with an embodiment of the disclosure;

FIG. 3A illustrates a perspective view of a PCB including L1 to L4 “+” or cross-shaped micro vias and oval shaped pads in L4 in accordance with an embodiment of the disclosure.

FIG. 3B illustrates a perspective view of the PCB including L1 to L4 “+” or cross-shaped micro vias and oval shaped pads in L4 of FIG. 3A rotated 45° in accordance with an embodiment of the disclosure.

FIG. 3C illustrates breakdown views of FIG. 3A in accordance with an embodiment of the disclosure.

FIG. 4A illustrates a perspective view of a PCB including L1 to L4 “+” or cross-shaped micro vias and round shaped pads in L4 in accordance with an embodiment of the disclosure;

FIG. 4B illustrates breakdown views of FIG. 4A in accordance with an embodiment of the disclosure;

FIG. 5A illustrates a conventional routing for L1 to L2 for a 0.5 mm pitch BGA (6 by 6) (prior art);

FIG. 5B illustrates the conventional routing for L2 to L3 for the 0.5 mm pitch BGA (6 by 6) of FIG. 5A (prior art);

FIG. 5C is an example sketch illustrating a space between trace and round pad;

FIG. 6A illustrates a routing using X-cross μVia for L1 to L2 for a 0.5 mm pitch BGA (6 by 6) in accordance with an embodiment of the disclosure;

FIG. 6B illustrates the routing using X-cross μVia for L2 to L3 for the 0.5 mm pitch BGA (6 by 6) of FIG. 6A in accordance with an embodiment of the disclosure;

FIG. 6C is an example sketch illustrating a wider trace and a wider space between trace and oval pad than that of FIG. 5C in accordance with an embodiment of the disclosure;

FIG. 7A illustrates a routing using X-cross μVia for L1 to L2 for a 0.4 mm pitch BGA (10 by 10) in accordance with an embodiment of the disclosure;

FIG. 7B illustrates a routing using X-cross μVia for L2 to L3 for a 0.4 mm pitch BGA (10 by 10) in accordance with an embodiment of the disclosure;

FIG. 7C illustrates the routing using X-cross μVia for L3-L4 for the 0.4 mm pitch BGA (10 by 10) of FIG. 7A in accordance with an embodiment of the disclosure;

FIG. 8A illustrates non-round micro via (e.g. oblong micro via) with non-round pad (e.g. oblong pad) in accordance with an embodiment of the disclosure;

FIG. 8B illustrates a PCB stack that includes stacked non-round micro vias of FIG. 8A without rotation from one layer to another subsequent layer in accordance with an embodiment of the disclosure;

FIG. 9A illustrates non-round micro via (e.g. oblong micro via) with rounded square pads in accordance with an embodiment of the disclosure;

FIG. 9B illustrates a PCB stack that includes stacked non-round micro vias of FIG. 9A with rotation of 90° from one layer to another subsequent layer and rounded square pads in non-breakout layer and oval pad in breakout layer in accordance with an embodiment of the disclosure;

FIG. 10A illustrates non-round micro via (e.g. Clover micro via) with round pads in accordance with an embodiment of the disclosure;

FIG. 10B illustrates a PCB stack that includes stacked non-round micro vias of FIG. 10A with rotation of 45° from one layer to another subsequent layer and round pads for both non-breakout layers and breakout layer in accordance with an embodiment of the disclosure;

FIG. 11A illustrates a perspective view of a PCB stack that includes staggered non-round micro vias in accordance with an embodiment of the disclosure;

FIG. 11B illustrates a front view of the stack of FIG. 11A in accordance with an embodiment of the disclosure;

FIG. 11C illustrates a side view of the stack of FIG. 11A in accordance with an embodiment of the disclosure;

FIG. 11D illustrates a top view of the stack of FIG. 11A in accordance with an embodiment of the disclosure; and

FIG. 12 is an optical image of micro vias of various shapes created by laser ablating in accordance with an embodiment of the disclosure.

### DETAILED DESCRIPTION

The disclosure may be understood by reference to the following detailed description, taken in conjunction with the drawings as described below. It is noted that, for purposes of illustrative clarity, certain elements in various drawings may not be drawn to scale.

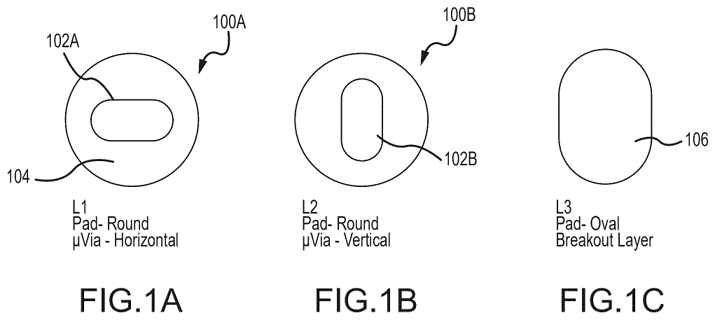

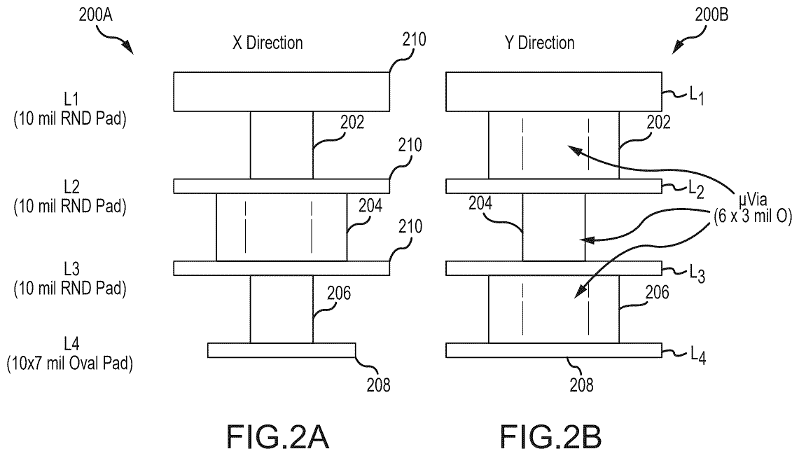

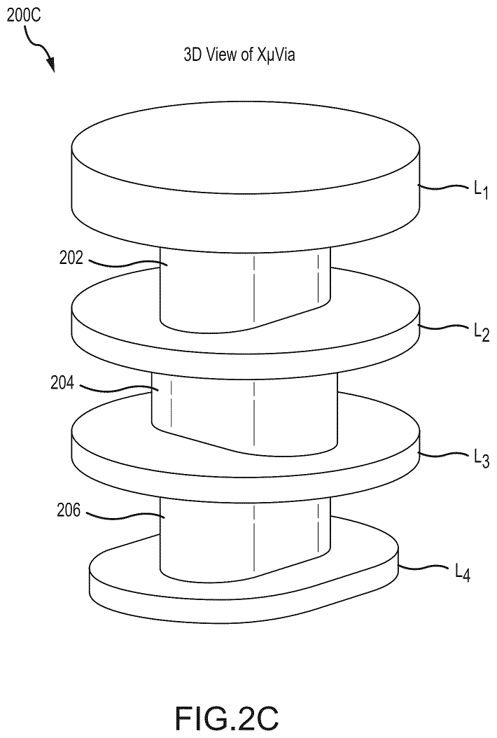

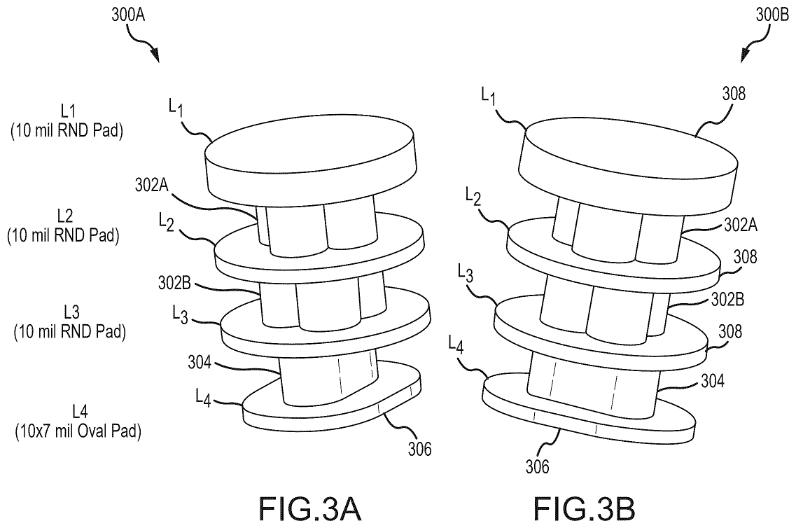

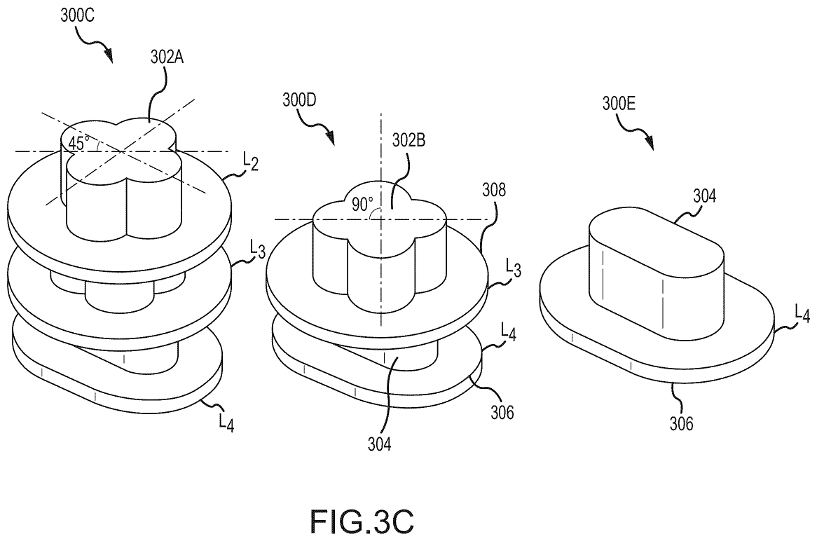

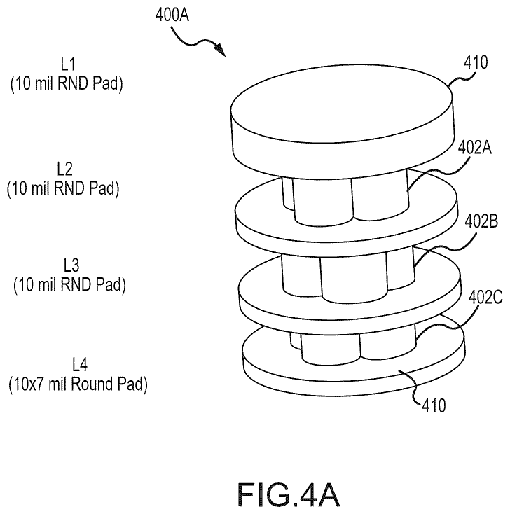

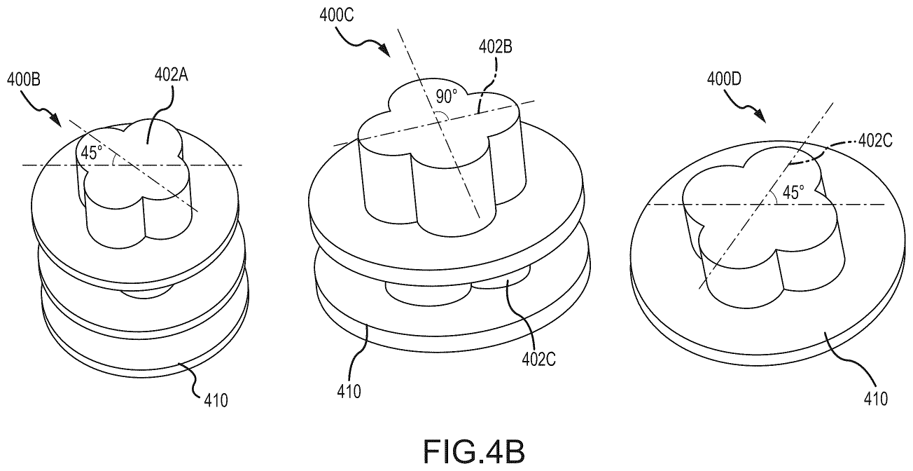

The disclosure addresses the need of improving reliability of micro vias and thus improve production yields by providing X-cross non-circular micro vias (e.g., oval micro vias or “+” or cross-shaped micro vias) for interconnecting layers. The X-cross non-circular micro vias may be better than the round via because of its impact on impedance and thickness of the routing trace and thus may help improve product reliability. The micro vias in a subsequent layer (e.g., between Layer 2 and Layer 3) may be rotated at any angle (e.g., 90 degrees) from the micro vias between Layer 1 and Layer 2 to create an X shape, or without any rotation. The micro vias in two different via layers create the X-cross micro vias, for example, X-cross oval-shaped micro vias as illustrated in FIGS. 1A-1C, FIGS. 2A-2C, and “+” or cross-shaped micro vias as illustrated in FIGS. 3A-3C, and FIGS. 4A-4B. In this disclosure, the oval shape is also referred to as the oblong shape. The terms “oval shape” and “oblong shape” are used interchangibly. Also, the cross-shaped micro via is also referred to as the Clover shaped micro via. The terms “cross-shaped micro via” and “Clover shaped micro via” are used interchangibly.

According to inter-process communication standard (IPCS) specification, the thickness of the dielectric layer in PCB may increase with the dimension or diameter of the vias. The thickness of the dielectric layer can affect the impedance and the thickness of the conductive trace or routing trace. When the dielectric layer is thin, the conductive trace or routing trace may become thin. A non-circular micro via (e.g. oval via) may help increase the thickness of the dielectric layer compared to a round micro via. For example, if the oval shape via may have a size of 6 mil by 3 mil, the dielectric layer can be about 4 mil thick. In contrast, if the via has a round shape with a diameter of 3 mil, the dielectric layer can be about 2 mil thick.

The X-cross non-circular μVia may improve μVia reliability, which may accommodate two or more stacked μVias. Also, the non-circular or non-round micro vias may reduce laser drill time when comparing 6 mil round via vs non-round via (e.g., 6 mil by 3 mil oval micro via), due to reduced size of the non-round via (e.g., about 44% less than a round via of 6 mil diameter).

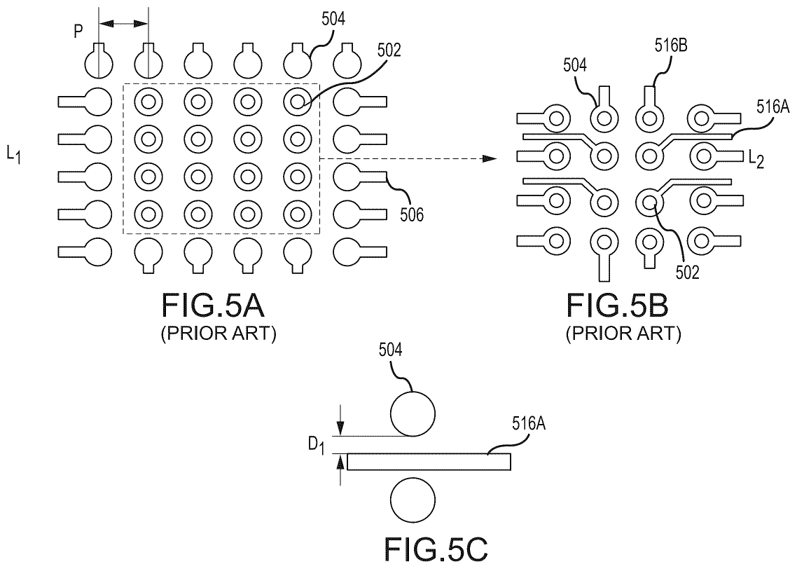

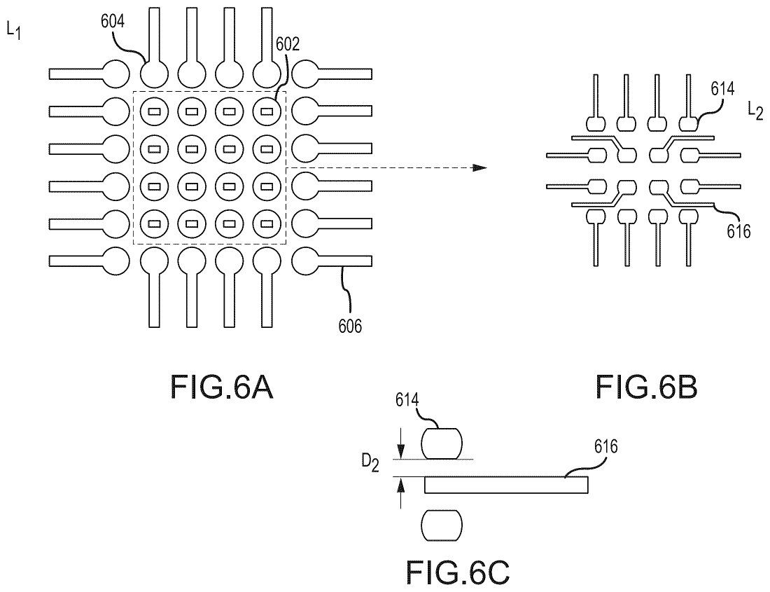

The disclosure also addresses the need for developing routing strategy at reduced costs by providing a design for BGA circuit components on a PCB using a combination of round pads and non-circular pads (e.g., oval pads) in multiple layers of the PCB. The round pads may be implemented for non-breakout layers while the oval pads may be used for breakout layers. The non-circular pads (e.g., oval pads) in the breakout layer may increase the routing trace width and the space between the routing trace and the non-circular pad and may improve yields in fabrication due to wider traces and wider space. For example, 0.5 mm pitch BGA 6×6 may use a trace width of about 4 mil and the space of about 4.33 mil, as illustrated in FIGS. 6A and 6B. In contrast, conventionally, a routing trace width of about 3 mil and the space size of about 3.33 mil may be used, as illustrated in FIGS. 5A-5B. More details will be provided in FIGS. 5A-5C and 6A-6B to demonstrate the impact of non-circular pads on the routing trace width and the space between the routing trace and the non-circular pad.

A conventional 0.4 mm pitch BGA allows only outer solder balls or outer pads to be routed and requires additional routing layers and multiple laminations for internal pads or internal solder balls. For example, a conventional PCB would include five layers and four laminations to breakout of a 10 by 10 0.4 mm BGA by using round pads and round vias.

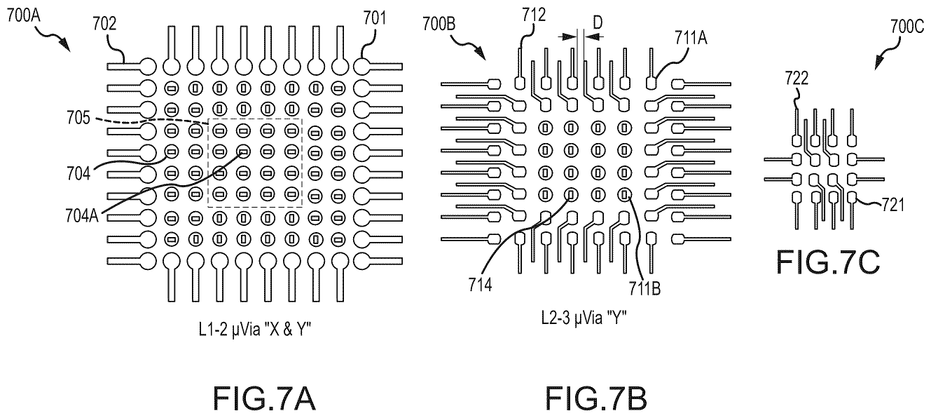

The present disclosure provides non-circular pads (e.g., oval pads) that allow routing of internal BGA solder balls, thus allow to breakout the BGA with fewer lamination layers, thereby reducing the number of laminations. For example, the disclosed PCB for breakout of the 10 by 10 0.4 mm BGA includes three layers and two laminations or two breakout layers by using the non-circular pads (e.g., oval pads), such as illustrated in FIGS. 7A-7C. Thus, the number of the four laminations for the conventional PCB is reduced to two laminations for the disclosed PCB.

The non-circular pads (e.g., oval pads) may allow routing to internal BGA pads, which are difficult to achieve based on conventional production capabilities. For example, a conventional 0.4 mm pitch BGA allows outer solder balls to be routed, while internal BGA pads or solder balls need to be routed in additional routing layers and multiple laminations. By using the non-circular pads or oval pads, a designer can reduce the number of breakout layers for routing internal solder balls, as illustrated in FIGS. 7A-7C.

Also, more breakout lines per BGA may reduce the number of routed layers or breakout layers and may reduce the number of laminations, which may significantly decrease the cost of printed wiring boards (PWBs) for customers by reducing lamination cycles, thus may increase overall production yield by reducing number of lamination cycles and reducing number of process steps. Factories may increase production throughput with reduced lamination cycles.

An example printed circuit board (PCB) may include three layers, i.e., Layer 1 (“L1”), Layer 2 (“L2”), and Layer 3 (“L3”). The PCB may also include X-cross oval micro vias (μVias), round pads in non-breakout layers, and oval pads in a breakout layer. The L1 to L2 oval shaped μVias (e.g., 3 mil×6 mil μVia) may connect between Layer 1 (“L1”) and Layer 2 (“L2”) may be created in a horizontal pattern.

FIG. 1A illustrates a printed circuit board (PCB) including L1 to L2 X-cross oval micro vias (μVias) with L1 round pad in accordance with an embodiment of the disclosure. As shown in FIG. 1A, L1 is a non-breakout layer including round pad 104. The term “L1 to L2 X-cross” refers to as interconnection between two layers, e.g. L1 and L2. L1 to L2 oval-shaped μVias 102A may connect between L1 and L2 in a horizontal pattern 100A.

FIG. 1B illustrates a PCB including L2 to L3 X-cross oval μVia with L2 round pad in accordance with an embodiment of the disclosure. As shown in FIG. 1B, L2 is also a non-breakout layer including round pad 104. L2 to L3 oval shaped μVias 102B may connect between L2 and L3 and may be created in a vertical pattern 100B. In the vertical pattern, the micro vias 102B may be rotated 90° from the horizontal pattern 100A. It will be appreciated by those skilled in the art that the micro vias in a subsequent micro via layer (e.g., between L2 to L3) may be rotated at any angle other than 90 degrees from the micro vias between L1 to L2 to create an X-cross. In other words, one pattern of micro vias is offset from another pattern of micro vias, which is referred to as “X and Y offset pattern” in the disclosure.

FIG. 1C illustrates a PCB Layer 3 including L3 oval pad in accordance with an embodiment of the disclosure. As shown in FIG. 1C, L3 is a breakout layer including oval-shaped pad 106. The breakout layer may include oval-shaped pad 106 to allow for additional routing space, which will be further described in details in FIGS. 6A-6C and FIGS. 7A-7C.

FIG. 2A illustrates a cross-sectional view (in an X-direction) of a PCB including L1 to L4 oval micro vias in accordance with an embodiment of the disclosure. As shown in FIG. 2A, a stack 200A includes four layers, i.e., L1 to L4 and X-cross non-round μVias connecting between L1 to L2, L2 to L3, and L3-L4. As shown in FIG. 2A, L1 to L2 μVia 202 stacks on top of L2 to L3 μVia 204, which stacks on top of L3-L4 μVia 206. The cross-sectional view of the stack 200A including X-cross non-round μVia looks quite different than a standard μVia. The stack 200A looks like stacking bricks on top of one another rotating the bricks at an angle (e.g., 90°). L2 to L3 μVia 204 looks bigger in than L1 to L2 μVia 202 in stack 200A. L3-L4 μVia 206 looks the same as L1 to L2 μVia 202 in stack 200A. L1 to L3 are non-breakout layers and have round pads or circular pads 210, while L4 is a breakout layer and has oval pad 208.

FIG. 2B illustrates a cross-sectional view (in a Y-direction) of the PCB including L1 to L4 oval micro vias of FIG. 2A rotated 90° in accordance with an embodiment of the disclosure. As shown in FIG. 2B, a stack 200B is rotated 90° from the stack 200A. As shown in FIG. 2B, L1 to L2 μVia 202 stacks on top of L2 to L3 μVia 204, which stacks on top of L3 to L4 μVia 206. L1 to L2 μVia 202 looks bigger in stack 200B than stack 200A. L1 to L3 pads 210 are circular shaped, thus look the same in stack 200B. In contrast, L4 pad 208 is oval shaped, thus looks smaller in stack 200A than in stack 200B. It will be appreciated by those skilled in the art that the angle for rotation may vary from 0° to 180°.

FIG. 2C illustrates a perspective view of the PCB including L1 to L4 oval micro vias of FIG. 2A or 2B in accordance with an embodiment of the disclosure. A stack 200C is a perspective view of stack 200A or 200B. As shown in FIG. 2C, L1 to L2 μVia 202 stacks on top of L2 to L3 μVia 204, which stacks on top of L3 to L4 μVia 206.

It will be appreciated by those skilled in the art that the oval shape pad may be replaced by any other non-circular pad.

The X and Y offset pattern may compensate for variations in thermal expansion (CTE) of different layers of the PCB in Z direction, help strengthen the μVia, and may improve reliability of the μVias. The potential increase in reliability of the stacked μVias may allow the users to avoid staggering μVias in their designs, as staggering μVias is employed in some designs today, requiring less space to breakout their HDI components (i.e., BGA) by reducing the transmission line signal length and improve signal integrity.

In some variations, the oval shaped micro via in non-breakout layers may be replaced with micro via with a ‘+’ shaped micro via, which may be rotated 45 degrees for every subsequent micro via layer, as illustrated in FIGS. 3A-3C. The micro via for the breakout layer would still use the oval shaped micro via and oval pad, as illustrated in FIGS. 3A-3C.

FIG. 3A illustrates a perspective view of a PCB including L1 to L4 “+” or cross-shaped micro vias and oval shaped pads in L4 in accordance with an embodiment of the disclosure. As shown in FIG. 3A, stack 300A includes four layers L1 to L4. L1, L2, and L3 are non-breakout layers. Each of L1, L2, L3 includes round pad 308. L1 to L2 “+” or cross-shaped micro via 302A connects between L1 and L2. L2 to L3 “+” or cross-shaped micro via 302B connects between L2 and L3. L4 is a breakout layer and includes oval pad 306. L3-L4 oval via 304 connects between L3 and L4.

FIG. 3B illustrates a perspective view of the PCB including L1 to L4 “+” or cross-shaped micro vias and oval shaped pads in L4 of FIG. 3A rotated 45° in accordance with an embodiment of the disclosure. Stack 300B is a perspective view rotated 45 degrees from the stack 300A. It will be appreciated by those skilled in the art that the angle for rotation may vary from 0° to 90°.

FIG. 3C illustrates breakdown views of FIG. 3A in accordance with an embodiment of the disclosure. As shown in FIG. 3C, stack 300C is a top perspective view of L1 to L2 “+” or cross-shaped micro vias 302A, which is on top of the round pad 308. Stack 300D is a top perspective view of L2 to L3 “+” or cross-shaped micro vias 302B, which is on top of L3 round pad 308. Stack 300E is a top perspective view of oval micro via 304 on top of L4 oval pad 306.

As an example, the round pads 308 for L1 to L3 may have a diameter of about 10 mil. The oval pad 306 for L4 may have a long axis dimension with a short axis dimension of 10 mil by 7 mil). The long axis of the oval pad is perpendicular to the short axis of the oval pad.

FIG. 4A illustrates a perspective view of a PCB including L1 to L4 “+” or cross-shaped micro vias (μVia) and round shaped L4 pads in accordance with an embodiment of the disclosure. FIG. 4B illustrates breakdown views of FIG. 4A in accordance with an embodiment of the disclosure.

As shown in FIGS. 4A-4B, rather than using an oval shaped micro via as illustrated in FIGS. 1A-1C, and 2A-2C, the micro via is cross-shaped (“+” or cross-shaped) . Stack 400A includes four layers, i.e., L1, L2, L3, and L4. Stack 400A also includes an L1 to L2 “+” or cross-shaped micro via 402A, which is stacked on top of L2 to L3 “+” or cross-shaped micro via 402B, which is stacked on top of L3-L4 “+” or cross-shaped micro via 402C. The micro vias are rotated 45 degrees for every subsequent micro via layer. For example, a second “+” or cross-shaped micro via 402B is rotated 45 degrees from a first “+” or cross-shaped micro via 402A. A third “+” or cross-shaped micro via 402C is rotated 45 degrees from the second “+” or cross-shaped micro via 402B. Each of L1 to L4 has round pads 410 (e.g., a diameter of 10 mil).

Stack 400B is a top perspective view of L1 to L2 “+” or cross-shaped micro vias 402A, which is on top of L2 round pad 410. Stack 400C is a top perspective view of L2 to L3 “+” or cross-shaped micro vias 402B, which is on top of L3 round pad 410. Stack 400D is a top perspective view of L3-L4 “+” or cross-shaped micro vias 402C, which is on top of L4 round pad 410.

In some variations, the breakout layer may use a round shaped micro via and round shaped pad, which may increase current capacity and the reliability of the micro via.

FIG. 5A illustrates a conventional routing for L1 to L2 for a 0.5 mm pitch BGA (6 by 6) (prior art). A pitch for BGA is defined as the distance P between two adjacent solder balls measured from center to center. As shown in FIG. 5A, layer L1 has thirty-six round pads 504.

Sixteen round vias 502 are used to connect between L1 and L2. A total of twenty outer pads 504 in L1 are routed by outer traces 506.

FIG. 5B illustrates the conventional routing for L2 to L3 for the 0.5 mm pitch BGA (6 by 6) of FIG. 5A (prior art). As shown in FIG. 5B, L2 includes four internal pads 504 that are routed by internal traces 516A. Twelve outer pads are also routed by outer traces 516B. The internal trace 516A has a width of 3 mil.

FIG. 5C is an example sketch illustrating space between a routing trace and a round pad. As shown in FIG. 5C, the space D1 is between the routing trace 516A and the round pad 504. As an example, when the round pad has a diameter of 10 mil, the closest space D1 between the internal trace 516A and the round pad 504 may be 3.3 mil. The dimension of the μVia 502 may be about 6 mils or less.

FIG. 6A illustrates a routing using X-cross μVia for L1 to L2 for a 0.5 mm pitch BGA (6 by 6) in accordance with an embodiment of the disclosure. As shown in FIG. 6A, L1 includes thirty-six round pads 604. Sixteen L1 to L2 oval vias 602 connect between L1 and L2. It will be appreciated by those skilled in the art that the oval vias may be any non-circular vias, such as “+” or cross-shaped via, among others.

FIG. 6B illustrates the routing using X-cross μVia for L2 to L3 for the 0.5 mm pitch BGA (6 by 6) of FIG. 6A in accordance with an embodiment of the disclosure. As shown in FIG. 6B, L2 has sixteen oval pads 614 connected to sixteen routing traces 616. The L2 oval pad 614 may have the dimensions of 10 mil by 6 mil, which has a smaller area than that of the L2 round pad 504, as illustrated in FIGS. 5A-5C.

FIG. 6C is an example sketch illustrating a wider trace and a wider space between trace and oval pad than that of FIG. 5C in accordance with an embodiment of the disclosure.

The shape of the oval pads 614 may allow the routing trace 616 to have a wider width than routing trace 516A for the 0.5 mm BGA (6 by 6), as shown in FIG. 6C. For example, the trace 616 has a width of 4 mil, which is wider than the width of 3 mil of the routing trace 516A, as illustrated in FIGS. 5B and 5C.

As illustrated in FIG. 6C, the closest space D2 between the internal trace 616 and the oval pad 614 is also wider than the space D1 between the internal trace 516A and the round pad 504 for the 0.5 mm BGA (6 by 6). For example, when the L2 oval pad 614 may have the dimensions of 10 mil by 6 mil, the L1 to L2 oval μVia 602 may have the dimensions of 6 mil by 3 mil, the space D2 may be 4.3 mils, which is also wider than the space D1 of 3.3 mil, as shown in FIG. 5C.

Without the use of oval pads, a total of four laminations are used to breakout the 10×10 BGA or provide the connections to each of 100 round pads. By using oval pads, the number of laminations can be reduced. For example, a 10×10 BGA uses a total of 2 laminations or two breakout layers, as shown in FIGS. 7B and 7C.

FIG. 7A illustrates a routing using L1 to L2 X-cross μVia for a 10×10 0.4 mm pitch BGA in accordance with an embodiment of the disclosure. As shown in FIG. 7A, configuration 700A shows that L1 is a non-breakout layer and includes thirty-six outer pads 701 connect to thirty-six routing traces 702. Configuration 700A also shows that L1 to L2 sixty-four oval vias 704 connect between L1 and L2. The L1 to L2 oval vias 704 are arranged in a mixture of a horizontal pattern (aligned on X-axis) and a vertical pattern (aligned on Y-axis), which may provide better reliability for the micro vias. The sixteen L2 to L3 internal oval vias 704A within contour 705 are arranged in a horizontal pattern. The mixture of vertical and horizontal non-round via patterns on the same layer as shown in 700A can be used to create additional routing channels on internal layers for internal balls within the contour (not illustrated).

FIG. 7B illustrates a routing using L2 to L3 X-cross oval μVia for the 10×10 0.4 mm pitch BGA of FIG. 7A in accordance with an embodiment of the disclosure. As shown in FIG. 7B, configuration 700B shows that L2 is a first breakout layer and includes fourty-eight outer non-circular (e.g., oval) pads 711A and sixteen inner round or circular pads 711B. The fourty-eight outer non-circular (e.g., oval) pads 711 are routed by fourty-eight routing traces 712, which can be wider than the traces by using round pads. Configuration 700B illustrates that sixteen L2 to L3 non-circular (e.g., oval) micro vias 714 are arranged in a vertical pattern (Y), which are rotated 90 degrees from the sixteen L1 to L2 internal non-circular (e.g., oval) micro vias 704A in the horizontal pattern that is shown in FIG. 7A.

FIG. 7C illustrates the routing for non-circular (e.g., oval) pads for the 10×10 0.4 mm pitch BGA of FIG. 7A in accordance with an embodiment of the disclosure. As shown in FIG. 7C, configuration 700C shows that L3 is a second breakout layer and includes sixteen non-circular (e.g., oval) pads 721 connected to sixteen routing traces 722. Again, the routing traces 722 can be wider than the traces by using round pads. As such, L1 has thirty-six routing traces 702, L2 has fourty-eight routing traces 712, and L3 has sixteen routing traces 722, a total of one hundred routing traces. The above design uses two laminations to breakout the 10 by 10 BGA.

The non-circular pads help reduce the number of laminations, which can reduce manufacturing costs. The non-circular pads may also improve production yield due to the use of wider traces and spaces for less or equal to 0.5 mm pitch BGAs.

Design may be more challenging as designers may account for the horizontal or vertical non-circular (e.g., oval) micro vias in the breakout pattern. Designers may also specify, in fabrication drawings, X-cross μVia size and directions (e.g., X-cross μViaH, X-cross μViaV in pad stacks).

### Experiments and Evaluations

Stress analysis may be performed to determine if there is any unexpected stress on the X-cross micro via that may determine if the structure has merits for further experiments.

Then, experiments will be performed to test the constructions of the X-cross micro via using current induced thermal cycling (CITC) testing. Experiments may also be performed to evaluate the reliability of X-cross μVia. Test coupons will be designed and made to test variations in materials, dielectric thicknesses, and size attributes of the micro via. Then, failure rates will be evaluated for each variation. The tests may help determine the ability to laser route and plate the μVias, and to determine reliability of the X-cross micro via designs.

Testing coupons may include (1) via size variations; (2) angle variations (for example, angle rotation between two layers). 90-degree rotation may be expected to optimize the reliability of the design; (3) different designs of the non-round vias may be evaluated. Some X-cross micro via may have higher current density than the non-circular (e.g., oval or “+” or cross-shaped) shape micro via; (4) BGA size variation, e.g., 10×10, 6×6, among others; (5) angle variations: a) one layer 0°, another layer 90°; b) one layer 45°, another layer 135°; (c) Angle between the first layer and second layer, less than 90°.

For example, experiments may be performed to determine if a 6 mil by 3 mil μVia can be plated with a 3.5 mil thick dielectric or greater. Experiments may also be performed to determine if a 6 mil by 3 mil μVia can be effectively drilled using laser with a 10 mil by 6 mil landing pad. Experiments may also be performed to determine if the smaller cross-sectional area of the non-circular (e.g., oval or “+” or cross-shaped) μVia allow for adequate current to power vias or ground vias. CITC testing may be performed to determine reliability of various μVia sizes and number of stacked X-cross μVias.

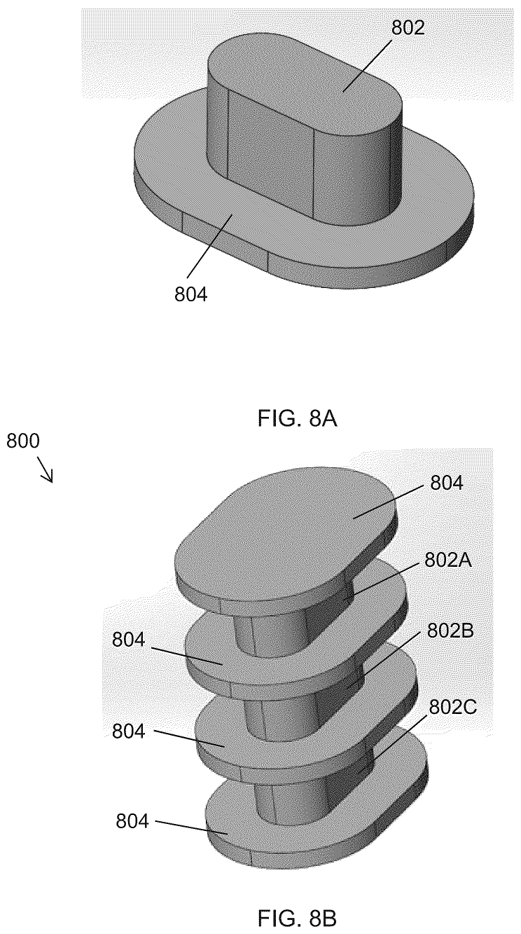

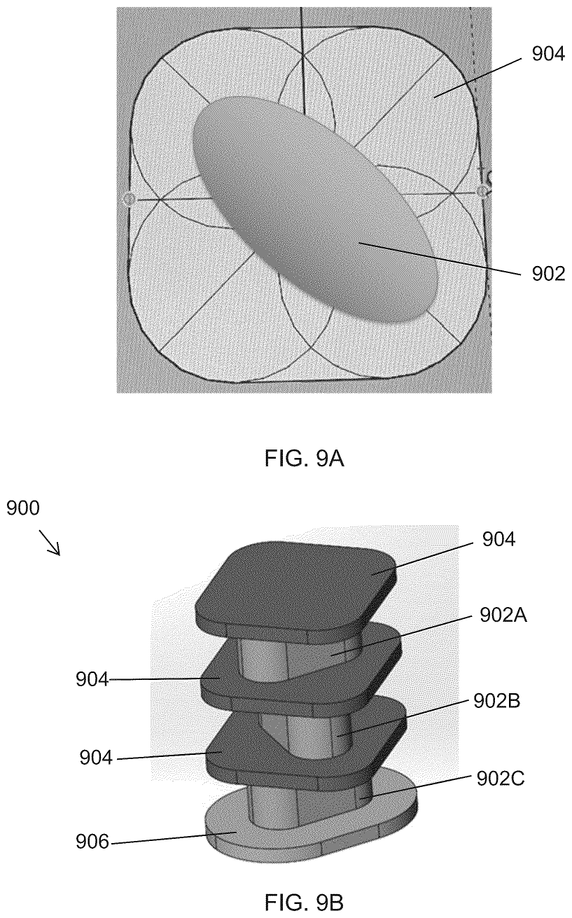

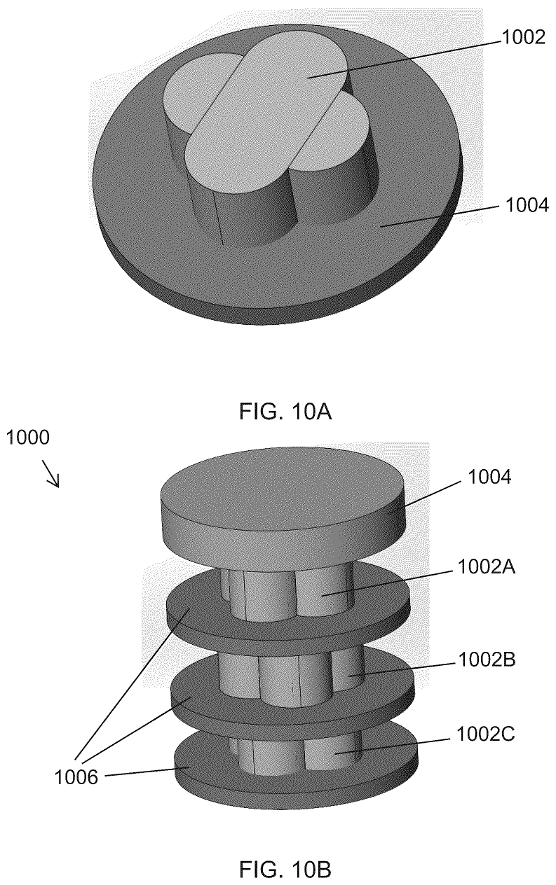

For example, round pads and round micro vias can be used as control samples in the experiments. The following stacks of micro vias will be tested, including (1) rounded square pads with oblong micro vias as shown in FIGS. 9A-9B; (2) oblong pads with oblong micro vias without rotation as shown in FIGS. 8A-8B; (3) round pads with Clover micro vias with 45 degrees rotation, as shown in FIGS. 10A-10B.

Based upon the experiments, the smallest size X-cross μVia may be identified to be reliable, which may affect less than 0.4 mm pitch BGA.

Evaluations may be performed to determine if the X-cross μVia pattern has any impact to very high-speed signals.

The potential benefits may include (1) gaining a competitive edge on some ultra HDI designs by offering the technology/design technique to customers; (2) reducing cost by reducing number of laminations; (3) reducing lamination cycles and increasing production yield and throughput; (4) increasing yields by using wider traces or spaces for 0.5 mm BGA or less than 0.5 mm pitch BGAs; (5) reducing manufacturing costs associated with laser drill and button plate; (6) improving production yield by having more reliable μVias; (7) designing more than 2 stack μVias; (8) reducing routing area for breakout by avoiding staggered μVias.

### EXAMPLES

The following examples are for illustration purposes only. It will be apparent to those skilled in the art that many modifications, both to materials and methods, may be practiced without departing from the scope of the disclosure.

Example dimensions for conventional design with circular pad or round pad for a 0.5 mm pitch BGA (6 by 6), as shown in FIGS. 5A-5B, are provided below for 1 track routing or trace:
(1) the width of the trace is 0.003″ or 3 mil (about 76 μm),
(2) the space D1 between a trace and the closest pad is 0.0033″ (about 84 μm),
(3) the diameter of the pad in Layer 1 (L1) is 0.010″ (about 254 μm).
(4) The μVia size may be about 6 mil or less.

Example dimensions for the present design of oval micro via and oval pad in Layer 2 for a 0.5 mm pitch BGA (6 by 6), as illustrated in FIGS. 6A-6B, are given below for 1 track routing:
(1) the width of the trace is 0.004″ or 4 mil (about 100 μm),
(2) the space D2 between a trace and the closest pad is 0.0043″ or 4.3 mil (about 109 μm),
(3) the diameter of the pads in Layer 1 is 0.010″ or 10 mil (about 254 μm),
(4) the dimensions of the oval pads in Layer 2 are 0.010″ (about 254 μm)×0.006″ (about 152 μm), and
(5) the dimensions of the oval micro vias are 0.006″ (about 152 μm)×0.003″ (about 76 μm).

Example dimensions for the present design of oval micro via and oval pad for a 0.4 mm pitch BGA (10 by 10), as illustrated in FIGS. 7A-7C, are given below for 1 track routing:
(1) the width of the trace is 0.003″ (about 76 μm). The trace width may vary depending on factory capabilities which may allow for the factory to increase or decrease spacing to maximize manufacturability.
(2) the space D between a trace and the closest pad, as illustrated in FIG. 7B, is 0.0033″ (about 84 μm). The space D may vary depending on factory capabilities which would allow for the factory to increase or decrease spacing to maximize manufacturability.
(3) the diameter of Layer 1 pad is 0.010″ (about 254 μm),
(4) the dimensions of the oval L1 to L2 micro via and the oval L2 to L3 micro via are 0.006″ (about 152 μm)×0.003″ (about 76 μm),
(5) the oval pads in Layer 2 (breakout layer) and Layer 3 (breakout layer) have the dimension of 0.010″ (about 254 μm)×0.006″ (about 152 μm), and
(6) the diameter of the round pads in Layer 1 is 0.010″ (about 254 μm).

### Stacked Non-Round Micro Vias Without Rotation Between Two Layers

FIG. 8A illustrates non-round micro via (e.g. oblong micro via) with non-round pad (e.g. oblong pad) in accordance with an embodiment of the disclosure. As shown, an oblong or oval shaped via 802 connects to an oblong or oval shaped pad 804.

FIG. 8B illustrates a PCB stack that includes stacked non-round micro vias of FIG. 8A without rotation from one layer to another subsequent layer in accordance with an embodiment of the disclosure. A stack of stacked micro vias 800 includes non-round micro vias 802A-C (oblong or oval shaped micro vias) connected between non-round pads (e.g oblong or oval shaped pads). The non-round micro vias 802A-C are aligned in the same direction without any rotation relative to each other. The stack 800 without rotation of the non-round micro vias helps maximize routing space.

### Rounded Square Pads for Non-Breakout Layers

FIG. 9A illustrates a non-round micro via (e.g. oblong micro via) with a rounded square pads in accordance with an embodiment of the disclosure. A rounded square pad 904 is illustrated in FIG. 9A. The rounded square pad 904 has nearly a square shape with four rounded corners. As shown, a non-round micro via 902 (e.g. oval shaped) is on top of the rounded square pad 904. The rounded square pads 904 can increase routing space for the non-breakout layers. The rounded square pads are also referred to as squircle pads. The terms “rounded square pad” and “squircle pad” are used interchangibly in the disclosure.

FIG. 9B illustrates a PCB stack that includes stacked non-round micro vias of FIG. 9A with rotation of 90 degrees from one layer to another subsequent layer and rounded square pads in non-breakout layer and oval pad in breakout layer in accordance with an embodiment of the disclosure. A stack of stacked micro vias 900 includes non-round micro vias 902A-B (oblong or oval shaped micro vias) connected between rounded square pads 904 for non-breakout layers, where the micro via 902B is rotated by 90° from the micro via 902A. The stack 900 also includes a non-rounded pad 906 (e.g. oval pad) for a breakout layer where the non-round micro via 902C is connected between the rounded square pad 904 and the non-circular pad 906 (oblong or oval pad) and is rotated 90° from the micro via 902B, but is aligned with micro via 902A. The rounded square pads or squircle pads can increase spacing for the non-breakout layers.

### Clover Micro Via With Round Pads

FIG. 10A illustrates a non-round micro via (e.g. Clover micro via) with a round pad in accordance with an embodiment of the disclosure. As shown in FIG. 10A, a non-rounded micro via 1002 (Clover micro via) is on top of a round pad 1004. The Clover micro via 1002 looks like a four leaf clover, similar to the cross-shaped micro via.

FIG. 10B illustrates a PCB stack that includes stacked non-round micro vias of FIG. 10A with rotation of 45 degrees from one layer to another subsequent layer and round pads in accordance with an embodiment of the disclosure. A stack 1000 includes non-round micro vias 1002A, 1002B and 1002C (Clover micro via). Each of the Clover micro via 1002A-C connected between two round pads 1006. The micro via 1002B is rotated 45 degrees from the above micro via 1002A, while the micro via 1002C is rotated 45 degrees from the above micro via 1002B. In this stack, the round pads 1006 are used for both the breakout layer and non-breakout layers.

This stack 1000 is similar to stack 400A.

### Staggered Micro Vias

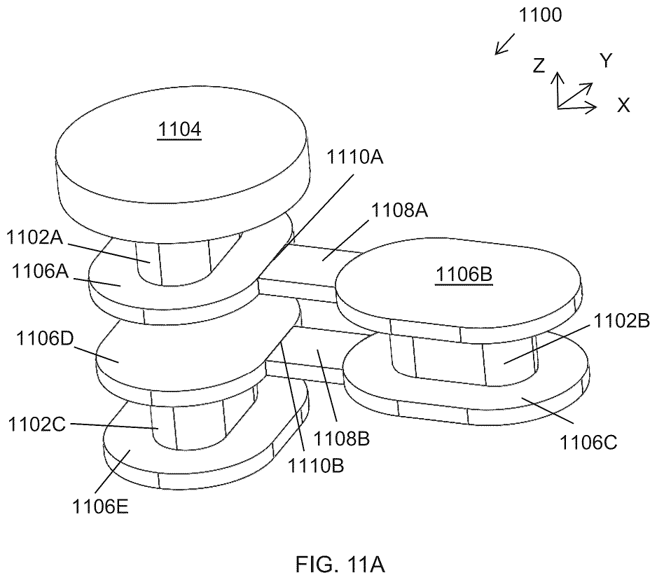

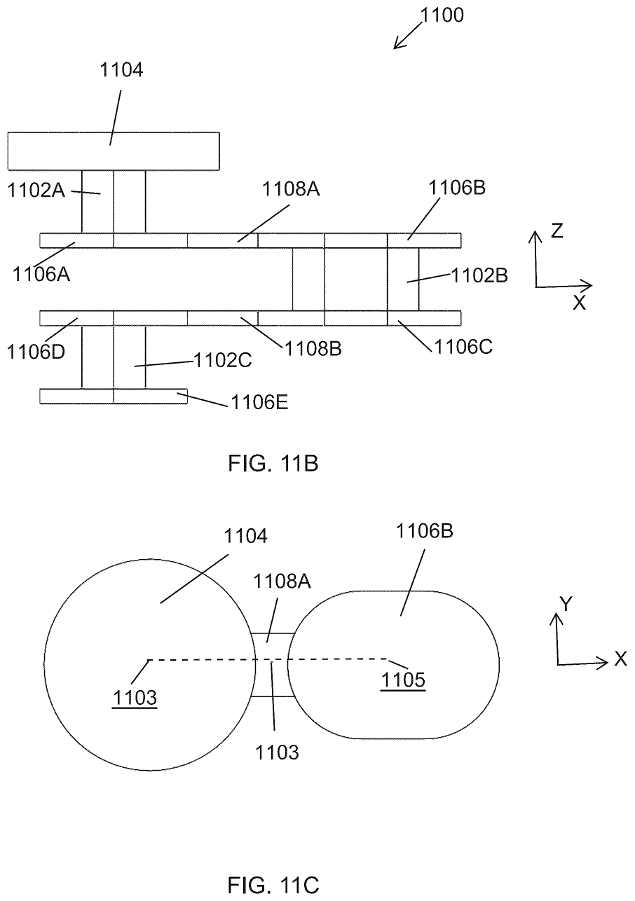

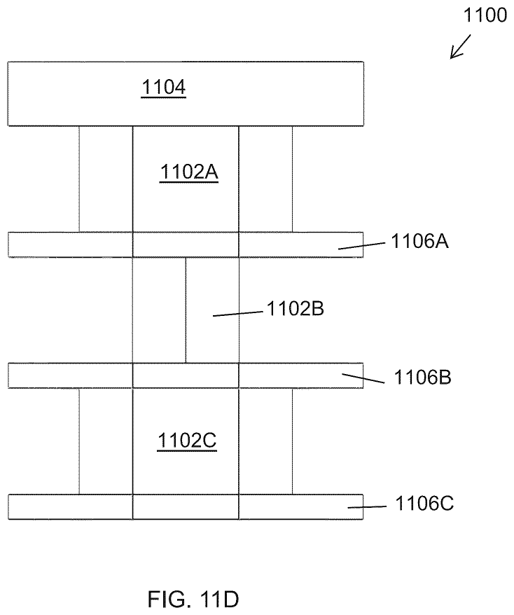

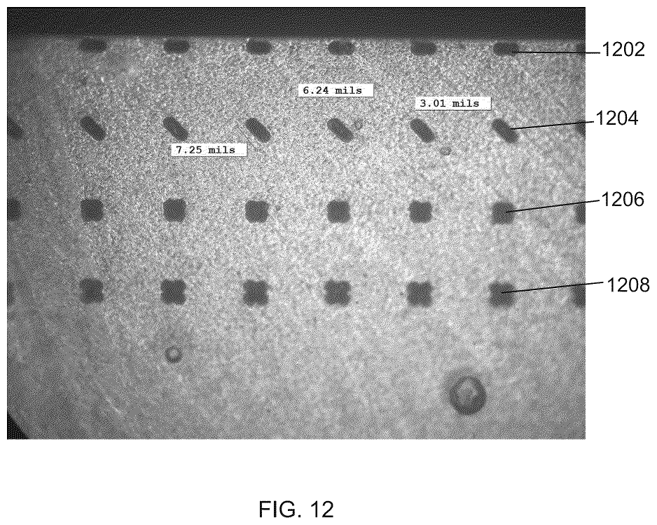

Non-round micro vias may also be implemented in a stack including staggered non-round micro vias, which may increase reliability than the stack including stacked micro vias. FIG. 11A illustrates a perspective view of a PCB stack that includes staggered non-round micro vias in accordance with an embodiment of the disclosure. A staggered configuration or stack 1100 includes non-round micro vias 1102A-1102C and non-round pads 1106A-1106E, with micro vias connected between respective pads. The staggered configuration 1100 includes a round pad 104 on its top, where the micro via 1102A connects between the round pad 1104 and the non-round pad 1106A.

As shown in FIG. 11A, the micro via 1102B connects between the upper non-circular pad 1106B and the lower non-circular pad 1106C, which extend outwardly from an edge 1110A of the non-round pad 1106A and an edge 1110B of the non-round pad 1106D, respectively.

The pads 1106B and 1106C are connected to the respective edges 1110A and 1110B of pads 1106A and 1106D via connection portions 1108A and 1108B, respectively. As such, micro via 1102B is offset from the upper micro via 1102A (between pads 1106A and 1104) and offset from the lower micro via 1102C (between pads 1106D and 1106E) along axis X. This configuration 1100 looks “unsteady” and is thus referred to as “staggered stack.”

Also, the non-round micro via 1102B is rotated 90 degrees from the micro vias 110A and 1102C, and the non-round pads 1106B and 1106C are rotated 90 degrees from the non-round pads 1106A, 1106D, and 1106E. In this example, the dimensions of the non-circular pads 1106A-D are the same. The non-circular pads 1106A-D are oval or oblong shaped, while non-round micro vias 1102A-1102C are oval or oblong shaped. A longitudinal axis of the oval pad is aligned with a longitudinal axis of the oval micro via. For example, the longitudinal axis of the oval pad 1106B is aligned with the longitudinal axis of the oval micro via 1102B along the X axis.

FIG. 11B illustrates a front view of the stack of FIG. 11A in accordance with an embodiment of the disclosure. As shown in FIG. 11B, the micro via 1102A is vertically aligned with the micro via 1102C along a Z axis, but is horizontally offset from the micro via 1102B along an X axis. The dimensions of non-circular pads 1106A and 1106E are smaller than the diameter of the circular pad 1104 along a horizontal axis X.

FIG. 11C illustrates a top view of the stack of FIG. 11A in accordance with an embodiment of the disclosure. As shown in the top view, the circular pad 1104 connects to non-circular pad 1106B by connection portion 1108A, which has a center 1107 aligned with a center 1103 of the circular pad 1104 and a center of non-circular pad 1105 along a horizontal axis X. Also, the circular pad 1104 covers the non-circular pad 1106D and 1106E, which is consistent with the front view shown in FIG. 11B. In this example, the length of the non-circular pad 1106B is the same as the diameter of the circular pad 1104.

FIG. 11D illustrates a side view of the stack of FIG. 11A in accordance with an embodiment of the disclosure. As shown in this side view, the length of the non-circular pads 1106A, 1106D, and 1106E are the same as the diameter of the circular pad 1104 on the top. The micro via 1102B is rotated 90 degrees from the micro via 1102A above and is also rotated 90 degrees from the micro via 1102C below.

FIG. 12 is an optical image of micro vias of various shapes created by laser ablating in accordance with an embodiment of the disclosure. The image of FIG. 12 shows that oval micro vias 1202 having length of 6.24 mils are aligned horizontally and oblong micro vias 1204 having length of 7.25 miles and width of 3.01 mils are aligned with an angle of about 45 degrees from a horizontal direction. Also, the image of FIG. 12 shows cross micro vias 1206 and Clover micro vias 1208 having similar dimensions to the oval micro vias and oblong micro vias.

While there have been shown and described what are at present the preferred embodiment of the invention, it will be obvious to those skilled in the art that various changes and modifications may be made therein without departing from the scope of the invention as defined by the claims.

Clause 1. A stack of layers for a printed circuit board (PCB), the stack comprising: a first layer comprising a first plurality of conductive pads spaced apart from each other; a second layer comprising a second plurality of conductive pads spaced apart from each other; a first plurality of non-circular shaped micro vias connecting between the first plurality of conductive pads of the first layer and the second plurality of conductive pads of the second layer; a third layer comprising a third plurality of conductive pads spaced apart from each other; a second plurality of non-circular shaped micro vias connecting between the second plurality of conductive pads of the second layer and the third plurality of conductive pads of the third layer, wherein the second plurality of non-circular shaped micro vias are rotated at a first angle from the first plurality of non-circular shaped micro vias to form an offset pattern along an X-Y plane.

Clause 2. The stack of clause 1, wherein the non-circular shaped micro vias comprise oval or oblong micro vias.

Clause 3. The stack of clause 2, wherein the third layer is a breakout layer, wherein the third plurality of conductive pads are non-circular shaped.

Clause 4. The stack of clause 2, further comprising: a fourth layer comprising a fourth plurality of conductive pads spaced apart from each other; and a third plurality of non-circular shaped micro vias connecting between the third plurality of conductive pads of the third layer and the fourth plurality of conductive pads of the fourth layer, wherein the third plurality of non-circular shaped micro vias are rotated at a second angle from the second plurality of non-circular shaped micro vias.

Clause 5. The stack of clause 4, wherein the fourth layer is a breakout layer, and the fourth plurality of conductive pads are non-circular shaped. 6.

Clause 7. The stack of clause 1, wherein the first angle ranges from 0 to 180 degrees.

Clause 8. The stack of clause 1, wherein the third layer is a breakout layer, wherein the non-circular shaped vias comprise “+” or cross-shaped micro vias.

Clause 9. The stack of clause 7, wherein the third plurality of conductive pads are circular shaped.

Clause 10. The stack of clause 7, further comprising: a fourth layer comprising a fourth plurality of conductive pads spaced apart from each other; and a third plurality of non-circular shaped micro vias connecting between the third plurality of conductive pads of the third layer and the fourth plurality of conductive pads of the fourth layer, wherein the third plurality of non-circular shaped micro vias are rotated at a second angle from the second plurality of non-circular shaped micro vias. 11.

Clause 12. The stack of clause 7, wherein the first angle ranges from 0 to 90 degrees.

Clause 13. The stack of clause 1, wherein the second plurality of non-circular shaped micro vias is aligned with the first plurality of non-circular shaped micro vias along a Z-axis perpendicular to the X-Y plane.

Clause 14. The stack of clause 1, wherein the second plurality of non-circular shaped micro vias is offset from the first plurality of non-circular shaped micro vias along an X-axis or a Y axis of the X-Y plane.

Clause 15. A stack of layers for a printed circuit board (PCB) including a ball grid array (BGA), the stack comprising: a first layer comprising circular pads or rounded square pads and a first set of routing traces, the circular pads or rounded square pads being divided into a first group of outer pads and a second group of inner pads, the first set of routing traces connecting to the first group of outer pads; a second layer comprising outer non-circular pads, inner circular or rounded square pads, and a second set of routing traces connecting to the outer non-circular pads; and a third layer comprising non-circular pads and a third set of routing traces connecting to the non-circular pads of the third layer.

Clause 16. The stack of clause 13, further comprising a first plurality of non-circular shaped micro vias connecting between a subset of the second group of the inner pads of the first layer and the outer non-circular pads of the second layer.

Clause 17. The stack of clause 14, further comprising a second plurality of non-circular shaped micro vias connecting between the inner circular or rounded square pads of the second layer and the non-circular pads of the third layer.

Clause 18. The stack of clause 15, wherein the second plurality of non-circular shaped micro vias are rotated at an angle from the first plurality of non-circular shaped micro vias to form an offset pattern along an X-Y plane with an offset angle ranging from 0 to 180 degrees.

Clause 19. The stack of clause 15, wherein each of the first plurality and the second plurality of the non-circular shaped micro vias comprise oval or oblong micro vias.

Clause 20. The stack of clause 15, wherein each of the first plurality and the second plurality of the non-circular shaped micro vias comprise “+” or cross-shaped micro vias.

Clause 21. The stack of clause 13, wherein the BGA has a pitch of 0.4 mm, wherein the BGA is a 10 by 10 array.

Clause 22. A stack of layers for a printed circuit board (PCB) including a ball grid array (BGA), the stack comprising: a first layer comprising circular pads or rounded square pads and a first set of routing traces, the circular pads or rounded square pads being divided into a first group of outer pads and a second group of inner pads, the first set of routing traces connecting to the first group of outer pads; and a second layer comprising non-circular pads and a second set of routing traces connecting to the non-circular pads.

Clause 21. The stack of clause 20, further comprising a plurality of non-circular shaped micro vias connecting between a subset of the second group of the inner pads of the first layer and the non-circular pads of the second layer.

Clause 22. The stack of clause 20, wherein the BGA has a pitch of 0.5 mm, wherein the BGA is a 6 by 6 array.

Any ranges cited herein are inclusive. The terms “substantially” and “about” used throughout this Specification are used to describe and account for small fluctuations. For example, they can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

Having described several embodiments, it will be recognized by those skilled in the art that various modifications, alternative constructions, and equivalents may be used without departing from the spirit of the invention. Additionally, a number of well-known processes and elements have not been described in order to avoid unnecessarily obscuring the invention. Accordingly, the above description should not be taken as limiting the scope of the invention.

Those skilled in the art will appreciate that the presently disclosed embodiments teach by way of example and not by limitation. Therefore, the matter contained in the above description or shown in the accompanying drawings should be interpreted as illustrative and not in a limiting sense. The following claims are intended to cover all generic and specific features described herein, as well as all statements of the scope of the method and system, which, as a matter of language, might be said to fall therebetween.

What is claimed is:

1. A stack of layers for a printed circuit board (PCB), the stack comprising:
a first layer comprising a first plurality of conductive pads spaced apart from each other;
a second layer comprising a second plurality of conductive pads spaced apart from each other;
a first plurality of non-circular shaped micro vias connecting between the first plurality of conductive pads of the first layer and the second plurality of conductive pads of the second layer;
a third layer comprising a third plurality of conductive pads spaced apart from each other;
a second plurality of non-circular shaped micro vias connecting between the second plurality of conductive pads of the second layer and the third plurality of conductive pads of the third layer,
wherein the second plurality of non-circular shaped micro vias are rotated at a first angle from the first plurality of non-circular shaped micro vias to form an offset pattern along an X-Y plane.

2. The stack of claim 1, wherein the non-circular shaped micro vias comprise oval or oblong micro vias.

3. The stack of claim 2, wherein the third layer is a breakout layer, wherein the third plurality of conductive pads are non-circular shaped.

4. The stack of claim 2, further comprising:
a fourth layer comprising a fourth plurality of conductive pads spaced apart from each other; and
a third plurality of non-circular shaped micro vias connecting between the third plurality of conductive pads of the third layer and the fourth plurality of conductive pads of the fourth layer, wherein the third plurality of non-circular shaped micro vias are rotated at a second angle from the second plurality of non-circular shaped micro vias.

5. The stack of claim 4, wherein the fourth layer is a breakout layer, and the fourth plurality of conductive pads are non-circular shaped.

6. The stack of claim 1, wherein the first angle ranges from 0 to 180 degrees.

7. The stack of claim 1, wherein the third layer is a breakout layer, wherein the non-circular shaped vias comprise “+” or cross-shaped micro vias.

8. The stack of claim 7, wherein the third plurality of conductive pads are circular shaped.

9. The stack of claim 7, further comprising:
a fourth layer comprising a fourth plurality of conductive pads spaced apart from each other; and
a third plurality of non-circular shaped micro vias connecting between the third plurality of conductive pads of the third layer and the fourth plurality of conductive pads of the fourth layer, wherein the third plurality of non-circular shaped micro vias are rotated at a second angle from the second plurality of non-circular shaped micro vias.

10. The stack of claim 7, wherein the first angle ranges from 0 to 90 degrees.

11. The stack of claim 1, wherein the second plurality of non-circular shaped micro vias is aligned with the first plurality of non-circular shaped micro vias along a Z-axis perpendicular to the X-Y plane.

12. The stack of claim 1, wherein the second plurality of non-circular shaped micro vias is offset from the first plurality of non-circular shaped micro vias along an X-axis or a Y axis of the X-Y plane.

13. A stack of layers for a printed circuit board (PCB) including a ball grid array (BGA), the stack comprising:
a first layer comprising circular pads or rounded square pads and a first set of routing traces, the circular pads or rounded square pads being divided into a first group of outer pads and a second group of inner pads, the first set of routing traces connecting to the first group of outer pads;
a second layer comprising outer non-circular pads, inner circular or rounded square pads, and a second set of routing traces connecting to the outer non-circular pads; and
a third layer comprising non-circular pads and a third set of routing traces connecting to the non-circular pads of the third layer.

14. The stack of claim 13, further comprising a first plurality of non-circular shaped micro vias connecting between a subset of the second group of the inner pads of the first layer and the outer non-circular pads of the second layer.

15. The stack of claim 14, further comprising a second plurality of non-circular shaped micro vias connecting between the inner circular or rounded square pads of the second layer and the non-circular pads of the third layer.

16. The stack of claim 15, wherein the second plurality of non-circular shaped micro vias are rotated at an angle from the first plurality of non-circular shaped micro vias to form an offset pattern along an X-Y plane with an offset angle ranging from 0 to 180 degrees.

17. The stack of claim 15, wherein each of the first plurality and the second plurality of the non-circular shaped micro vias comprise oval or oblong micro vias.

18. The stack of claim 15, wherein each of the first plurality and the second plurality of the non-circular shaped micro vias comprise “+” or cross-shaped micro vias.

19. The stack of claim 13, wherein the BGA has a pitch of 0.4 mm, wherein the BGA is a 10 by 10 array.

20. A stack of layers for a printed circuit board (PCB) including a ball grid array (BGA), the stack comprising:
a first layer comprising circular pads or rounded square pads and a first set of routing traces, the circular pads or rounded square pads being divided into a first group of outer pads and a second group of inner pads, the first set of routing traces connecting to the first group of outer pads; and
a second layer comprising non-circular pads and a second set of routing traces connecting to the non-circular pads.

21. The stack of claim 20, further comprising a plurality of non-circular shaped micro vias connecting between a subset of the second group of the inner pads of the first layer and the non-circular pads of the second layer.

22. The stack of claim 20, wherein the BGA has a pitch of 0.5 mm, wherein the BGA is a 6 by 6 array.
